(19) United States
(12) Patent Application Publication
(10) Pub. No.: US 2021/0234316 A1
(43) Pub. Date: Jul. 29, 2021

(54) SHIELD FOR PANEL CONNECTORS

(71) Applicant: ARRIS Enterprises LLC, Suwanee, GA (US)

(72) Inventors: Keith SIBLEY, North Wales, PA (US); Paul FITZGERALD, Warrington, PA (US); Luis LOPEZ, Apodaca (MX); Jonathan PRIDGEON, Saltaire (GB); Antonio CALLEGARIS, Shipley (GB); Andrew SOUTH, Saltaire (GB); Matthew GREGG, Saltaire (GB); Antony BRISTOW, Halifax (GB); Neil MASON, Burnley (GB); Andres CASTILLO, Saltaire (GB)

(21) Appl. No.: 17/159,325

(22) Filed: Jan. 27, 2021

Related U.S. Application Data
(60) Provisional application No. 62/966,141, filed on Jan. 27, 2020.

(51) Int. Cl. H01R 13/6587; H01R 12/70

(52) U.S. Cl. CPC H01R 13/6587; H01R 2201/04; H01R 2201/18; H01R 12/7076

(57) ABSTRACT

A shield includes a cover, a first frame, and a second frame. The first frame is configured to be attached to a first side of a circuit board. The second frame is configured to be attached to a second side of the circuit board. The cover is configured to be attached to the first frame and the second frame such that the cover is configured to overlap a portion of the first side of the circuit board, a portion of the second side of the circuit board, and a portion of a third side of the circuit board. The cover, the first frame, and the second frame are configured to together define a housing. An apparatus includes the shield and the circuit board.

### BACKGROUND

A popular electronic apparatus in many homes is the so-called “set-top-box” (STB), which houses electronic circuits that convert signals from an input line into signals usable by end devices for displaying data and audio/video media content such as television programing and movies.

The STB may be provided with interfaces including connectors to securely deliver the content to a physically connected end device. For example, such interfaces can be a High-Definition Multimedia Interface (HDMI) and/or a Universal Serial Bus (USB) interface. Connection between the STB and the end device can be through a cable. Typical STB technologies, such as HDMI and USB, include digital signaling that can produce harmonics, for example, in the 2.4 GHz and 5 GHz frequency bands. HDMI and USB connectors that are used can resonate these harmonics, thereby degrading the performance of various wireless technologies that operate in these frequency bands such as wireless local area network (WLAN), Bluetooth, and RF4CE. Accordingly, shields may be provided around connectors to reduce gaps between the shields and circuit board grounds in order to mitigate such electromagnetic interference (EMI).

Existing solutions involve mounting a top shield with an attachable top cover on a top side of a circuit board and mounting a bottom shield with an attachable bottom cover on a bottom side of the circuit board.

However, the existing solutions require a higher number of parts and do not adequately insulate the front edges of the connectors thereby requiring secondary gaskets. Therefore, the existing solutions are complex, expensive and burdensome to assemble.

Thus, it would be advantageous and an improvement over the existing solutions to provide a shield that has a lower number of parts and is capable of reducing EMI by effectively insulating front edges of connectors without secondary gaskets.

### SUMMARY

A shield for use with an apparatus (such as in an STB with a connected television) is disclosed in the present application.

The shield comprises:

a cover;

a first frame; and

a second frame,

wherein:

the first frame is configured to be attached to a first side of a circuit board;

the second frame is configured to be attached to a second side of the circuit board;

the cover is configured to be attached to the first frame and the second frame such that the cover is configured to overlap a portion of the first side of the circuit board, a portion of the second side of the circuit board, and a portion of a third side of the circuit board; and

the cover, the first frame, and the second frame are configured to together define a housing.

### BRIEF DESCRIPTION OF THE DRAWINGS

FIG. 1 is a perspective view of an example apparatus including an exemplary implementation of a shield 100 and a circuit board assembly 200.

FIG. 2 is another perspective view of the example apparatus including the exemplary implementation of the shield 100 and the circuit board assembly 200.

FIG. 3 is an exploded perspective view of the example apparatus.

FIG. 4 is another exploded perspective view of the example apparatus.

FIG. 5A is a cross-sectional view of the example apparatus taken along Line 5A-5A in FIG. 1.

FIG. 5B is a detailed view of portion 5B-5B in FIG. 5A.

FIG. 5C is a detailed view of portion 5C-5C in FIG. 5A.

### DETAILED DESCRIPTION

Exemplary embodiments will be described in detail below with reference to the drawings. The description and drawings are provided so that a person skilled in the art can fully understand the present disclosure and are not intended to limit the subject matter recited in the claims.

The shield and apparatus disclosed herein provide a single side mounted cover which can be simultaneously attached to both a top frame and a bottom frame and make positive contact with sides of connectors in order to effectively insulate front edges of the connectors.

The shield and apparatus disclosed herein address and solve the following problems:

How to reduce EMC/FCC spur issues between connectors of an electronic device.

How to solidly insulate the connectors of the electronic device by creating a Faraday's cage trapping energy inside a shield.

How to eliminate the need for secondary gaskets in a shield.

How to reduce assembly time and cost of a shield.

How to leverage the solution to the above-mentioned problems in a shield with a minimal number of parts.

The shield and apparatus disclosed herein solve the problems identified above and provide an efficient and cost effective solution to reduce EMI by effectively insulating front edges of connectors.

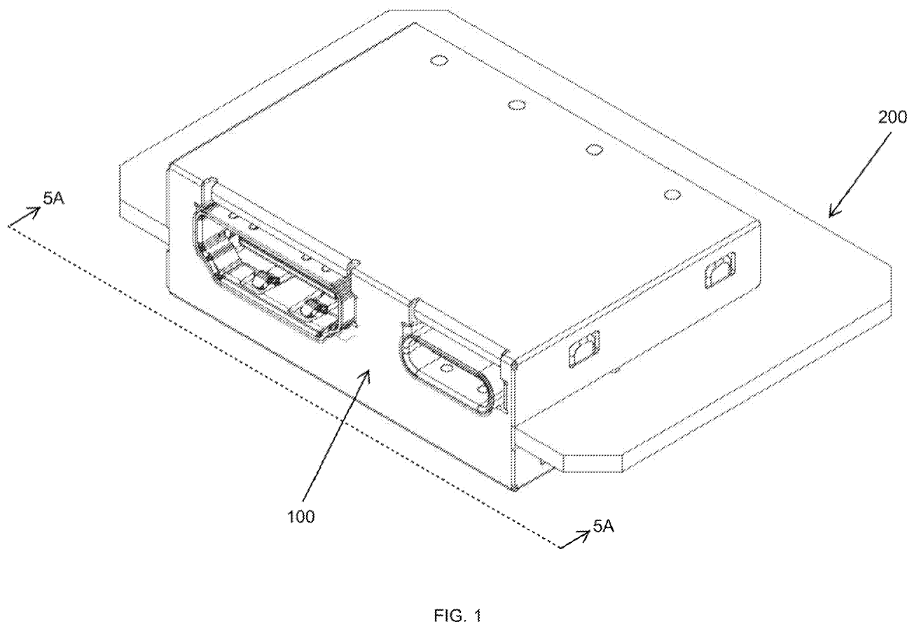

FIG. 1 is a perspective view of an example apparatus including an exemplary implementation of a shield 100 and a circuit board assembly 200. The apparatus may be part of an STB or other standalone device, or may be incorporated in a television or other content playing apparatus, or other device and the scope of the present invention is not intended to be limited to such forms.

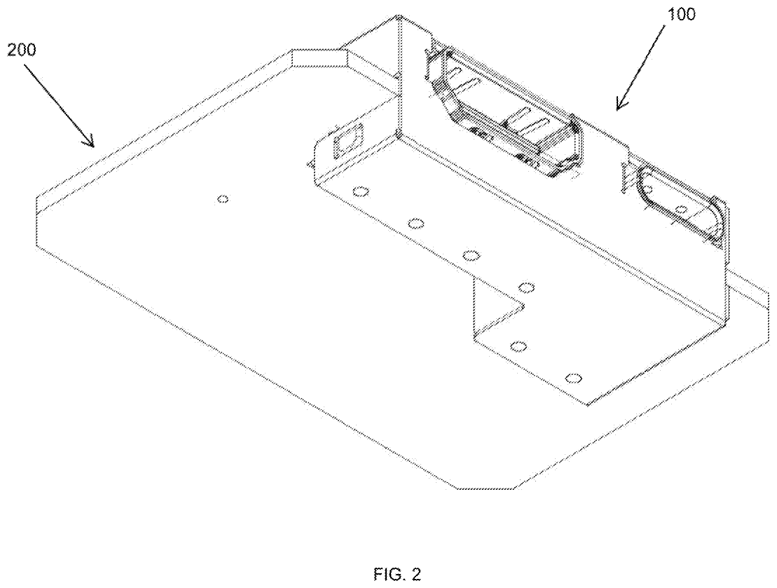

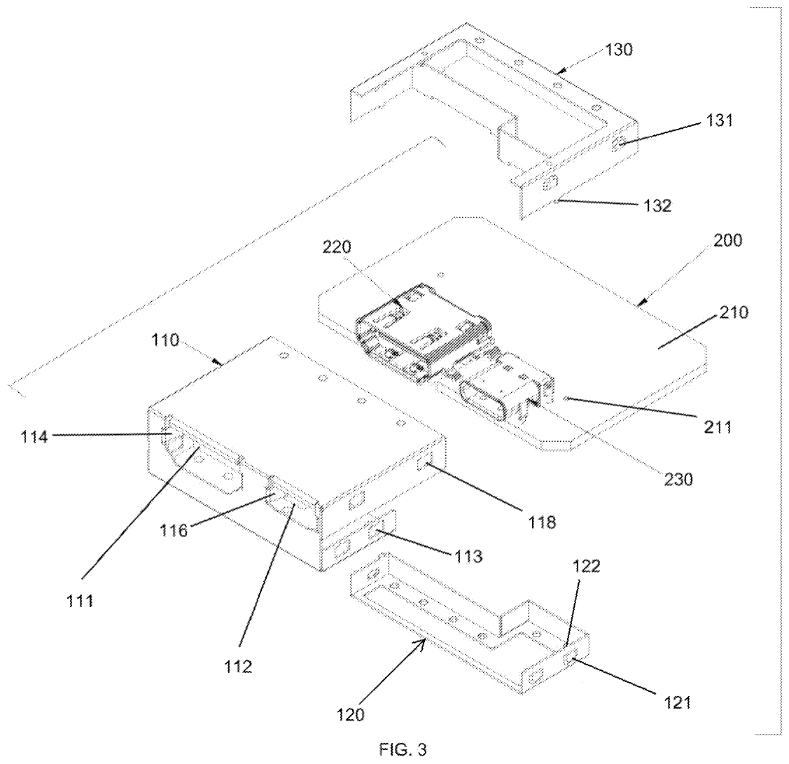

FIG. 2 is another perspective view of the example apparatus including the exemplary implementation of the shield 100 and the circuit board assembly 200. The shield 100 may include a cover 110, a first frame 120 and a second frame 130 (see FIGS. 3 & 4). The cover 110 may overlap the first frame 120 and the second frame 130. The circuit board assembly 200 may include a circuit board 210, a first connector 220 and a second connector 230 (see FIGS. 3 & 4). In some embodiments, one of the first connector 220 and the second connector 230 may be an HDMI connector and the other of the first connector 220 and the second connector 230 may be a USB connector. Alternatively, either connector 220 or 230 can include, but is not limited to, a parallel connection, a serial connection, a coaxial connection, or any other connection to external devices known in the art.

FIG. 3 is an exploded perspective view of the example apparatus. As shown in the embodiment of FIG. 3, the first frame 120 may be attached to a bottom side of the circuit board 210. The second frame 130 may be attached to a top side of the circuit board 210. The cover 110 may be attached to the first frame 120 and the second frame 130 such that the cover 110 overlaps a portion of the top side of the circuit board 210, a portion of a front side of the circuit board 210, and a portion of the bottom side of the circuit board 210. The cover 110, the first frame 120, and the second frame 130 may together define a housing. The housing may create a Faraday's cage trapping energy inside the shield 100.

Any of the cover 110, the first frame 120, and the second frame 130 may be of single piece construction. The shield 100 may thus be comprised of three parts.

For example, the cover 110 may include a top wall, a front wall, a bottom wall, and side walls. The front wall of the cover 110 may constitute a front side of the shield 100. The first frame 120 may include a bottom wall with a central cutout, side walls, and a rear wall with an offset or bump-out to accommodate connectors 220, 230 of different sizes. The second frame 130 may include side walls, a rear wall, and a central wall with an offset or bump-out to accommodate connectors 220, 230 of different sizes.

The cover 110 may include an opening 111 or 112 configured to receive a connector 220 or 230 on the circuit board 210. In some embodiments, the cover may include a first opening 111 configured to receive a first connector 220 on the circuit board 210 and a second opening 112 configured to receive a second connector 230 on the circuit board 210. The connectors 220, 230 may be fastened to the circuit board 210 by clips or by any other fastening arrangement known in the art. Any number of openings and connectors may be provided.

The cover 110 may include an aperture 113 and the first frame 120 may include a protrusion 121 configured to mate with the aperture 113 so as to fasten the cover 110 to the first frame 120. The cover 110 may include an aperture 118 and the second frame 130 may include a protrusion 131 configured to mate with the aperture 118 so as to fasten the cover 110 to the second frame 130. Any number of apertures and protrusions may be provided. Alternatively or in addition, any other fastening arrangement known in the art can be provided.

The first frame 120 may include a projection 122 configured to mate with an aperture 211 of the circuit board 210 so as to fasten the first frame 120 to the circuit board 210. The second frame 130 may include a projection 132 configured to mate with an aperture 211 of the circuit board 210 so as to fasten the second frame 130 to the circuit board 210. Any number of apertures and projections may be provided. Alternatively or in addition, any other fastening arrangement known in the art can be provided.

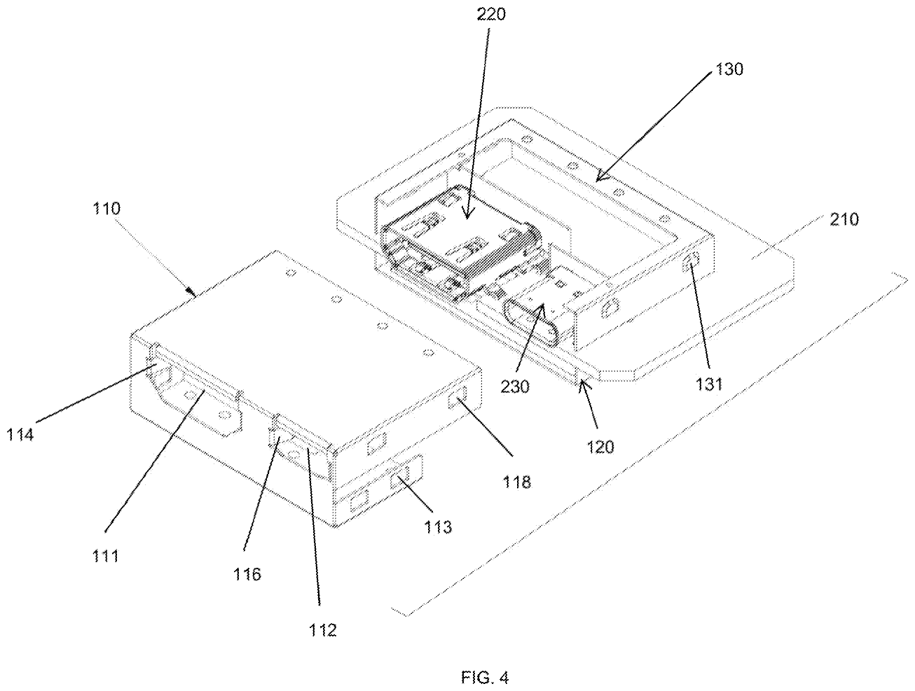

FIG. 4 is another exploded perspective view of the example apparatus. The first frame 120 and the second frame 130 may first be attached to the circuit board 210. Thereafter, the cover 110 may be attached to the first frame 120 and the second frame 130 simultaneously. Either or both of the first frame 120 and the second frame 130 can be joined to the circuit board 210, for example, by soldering.

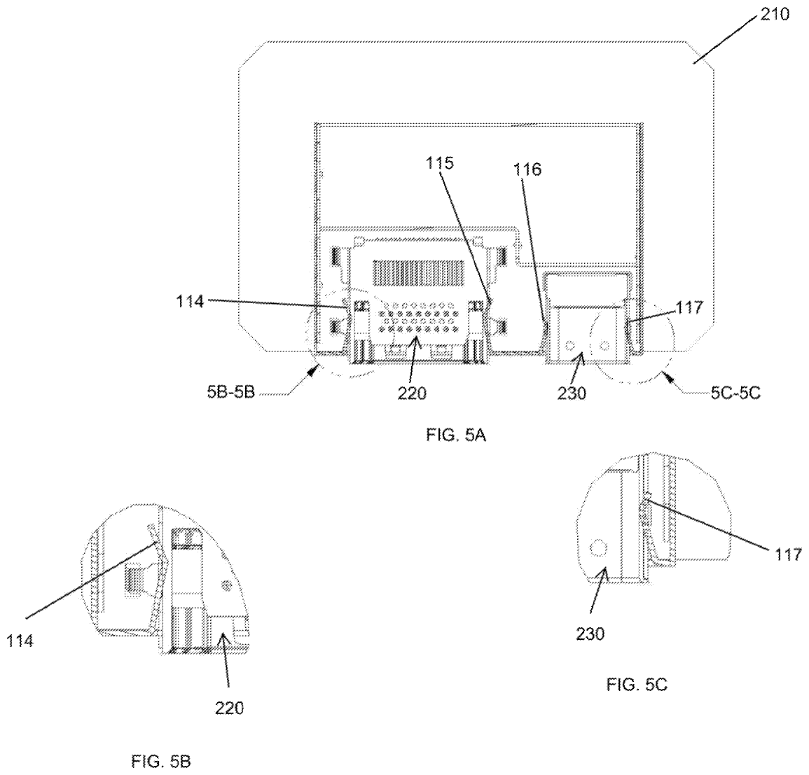

FIG. 5A is a cross-sectional view of the example apparatus taken along Line 5A-5A in FIG. 1. FIG. 5B is a detailed view of portion 5B-5B in FIG. 5A. FIG. 5C is a detailed view of portion 5C-5C in FIG. 5A. The cover 110 may include a tab 114 or 115. The tab 114 or 115 may configured to make contact with a connector 220 or 230 on the circuit board 210. As shown in the embodiments of FIGS. 5A-5C, the cover 110 may include a first tab 114, a second tab 115, a third tab 116, and a fourth tab 117. The first tab 114 and the second tab 115 may configured to make contact with respective sides of a first connector 220 on the circuit board 210. The third tab 116 and the fourth tab 117 may be configured to make contact with respective sides of a second connector 230 on the circuit board 210. Each of the tabs 114-117 may be adjacent to one of the openings 111 or 112 and may extend rearwardly from the front wall of the cover 110. Any of the tabs 114-117 may be flexible. In some variations, each of the tabs 114-117 may be bent or deflected such that a medial portion of the tab 114, 115, 116 or 117 is in contact with a side of one of the connectors 220 or 230. The shield 100 can therefore make positive contact with multiple sides of the connectors 220, 230 to thereby insulate the front edges of the connectors 220, 230 and help reduce EMC/FMC spur issues. Consequently, the part count of the shield 100 is minimized and secondary gaskets are unnecessary. Any number of tabs may be provided. Alternatively or in addition, any other positive contact arrangement known in the art can be provided.

Any of the cover 110, the first frame 120 and the second frame 130 may be comprised of plastic and/or metal. Alternatively or in addition, any other construction material known in the art can be used.

It is also contemplated that the implementation of the components of the present invention can be done with any newly arising technology that may replace any of the above implementation technologies.

In view of the above, the shield and apparatus disclosed herein solve the problems of existing solutions and provide an efficient and cost effective solution to reduce EMI by effectively insulating front edges of connectors.

We claim:

1. A shield comprising:
a cover;
a first frame; and
a second frame,
wherein:
the first frame is configured to be attached to a first side of a circuit board;
the second frame is configured to be attached to a second side of the circuit board;
the cover is configured to be attached to the first frame and the second frame such that the cover is configured to overlap a portion of the first side of the circuit board, a portion of the second side of the circuit board, and a portion of a third side of the circuit board; and
the cover, the first frame, and the second frame are configured to together define a housing.

2. The shield of claim 1, wherein the cover includes an opening configured to receive a connector on the circuit board.

3. The shield of claim 2, wherein the connector is an HDMI connector or a USB connector.

4. The shield of claim 1, wherein:
the cover includes an aperture;
one of the first frame and the second frame includes a protrusion; and
the protrusion is configured to mate with the aperture.

5. The shield of claim 1, wherein:
the cover includes a tab; and
the tab is configured to make contact with a connector on the circuit board.

6. The shield of claim 5, wherein the connector is an HDMI connector or a USB connector.

7. The shield of claim 1, wherein:
the cover includes a first tab, a second tab, a third tab, and a fourth tab;
the first tab and the second tab are configured to make contact with respective sides of a first connector on the circuit board; and
the third tab and the fourth tab are configured to make contact with respective sides of a second connector on the circuit board.

8. The shield of claim 7, wherein one of the first connector and the second connector is an HDMI connector and the other of the first connector and the second connector is a USB connector.

9. The shield of claim 1, wherein one of the first frame and the second frame includes a projection configured to mate with an aperture of the circuit board.

10. The shield of claim 1, wherein the cover is of single piece construction.

11. An apparatus comprising:
a circuit board; and
a shield;
wherein:
the shield comprises a cover, a first frame, and a second frame;
the first frame is configured to be attached to a first side of a circuit board;
the second frame is configured to be attached to a second side of the circuit board;
the cover is configured to be attached to the first frame and the second frame such that the cover is configured to overlap a portion of the first side of the circuit board, a portion of the second side of the circuit board, and a portion of a third side of the circuit board; and
the cover, the first frame, and the second frame are configured to together define a housing.

12. The apparatus of claim 11, further comprising a connector on the circuit board.

13. The apparatus of claim 12, wherein the cover includes an opening configured to receive the connector.

14. The apparatus of claim 12, wherein the connector is an HDMI connector or a USB connector.

15. The apparatus of claim 12, wherein:
the cover includes a tab; and
the tab is configured to make contact with the connector on the circuit board.

16. The apparatus of claim 11, wherein:
the cover includes a first tab, a second tab, a third tab, and a fourth tab;
the first tab and the second tab configured to make contact with respective sides of a first connector on the circuit board; and
the third tab and the fourth tab are configured to make contact with respective sides of a second connector on the circuit board.

17. The apparatus of claim 16, wherein one of the first connector and the second connector is an HDMI connector and the other of the first connector and the second connector is a USB connector.

18. The apparatus of claim 11, wherein:
the cover includes an aperture;
one of the first frame and the second frame includes a protrusion; and
the protrusion is configured to mate with the aperture.

19. The apparatus of claim 11, wherein one of the first frame and the second frame includes a projection configured to mate with an aperture of the circuit board.

20. The apparatus of claim 11, wherein the cover is of single piece construction.
